(19) United States
(12) Patent Application Publication
(10) Pub. No.: US 2026/0372113 A1
(43) Pub. Date: Nov. 19, 2026

(54) DIFFRACTION-BASED OVERLAY MARK DESIGN

(71) Applicant: Taiwan Semiconductor Manufacturing Co., Ltd., Hsinchu (TW)

(72) Inventors: Ting-Wei TANG, Hsinchu (TW); Ming-Jhih KUO, Hsinchu (TW)

(73) Assignee: Taiwan Semiconductor Manufacturing Co., Ltd., Hsinchu (TW)

(21) Appl. No.: 19/750,845

(22) Filed: Jul. 22, 2026

Related U.S. Application Data
(62) Division of application No. 18/404,639, filed on Jan. 4, 2024.

(51) Int. Cl. H10W 46/00; H10P 76/20

(52) U.S. Cl. CPC H10W 46/00; H10P 76/2041; H10W 46/301

(57) ABSTRACT

An integrated circuit includes a device region and an overlay mark region. The device region includes a plurality of transistors and metal connection structures above the transistors. The overlay mark region includes a first diffraction grating of first conductive structures, a shield grating of elongated structures, and a second diffraction grating of second conductive structures above the shield grating and the first diffraction grating. A plurality of the first conductive structures is positioned laterally between each pair of adjacent second conductive structures.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

However, as transistor features, and corresponding metal interconnect structures decrease in size, alignment tolerances decrease. As one example, conductive vias are utilized to contact source/drain contacts and gate electrodes. Misalignment of conductive vias can mean that the conductive vias do not contact the intended source/drain contact or gate electrode. Furthermore, metal lines are formed in metal layers (e.g., metal 0, metal 1 etc.) to contact the conductive vias. Misalignment of the metal layers in relation to the conductive vias, or to lower metal layers, can result in nonfunctioning integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are top views and cross-sectional views of an overlay mark region and a device region of an integrated circuit, in accordance with some embodiments.

FIG. 1G is a block diagram of a photolithography system, in accordance with some embodiments.

FIG. 1H is a top view of a wafer, in accordance with some embodiments.

FIG. 1I is a simplified top view of an integrated circuit, in accordance with some embodiments.

FIGS. 2A-2B are cross-sectional views of a mask overly region, in accordance with some embodiments.

FIG. 3 is a top view of an overlay mark region of an integrated circuit, in accordance with some embodiments.

FIG. 4 is a flow diagram of a method for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide a method and structure for improved alignment of features in wafer processing. Embodiments of the present disclosure provide an enhanced overlay mark region that enables improved diffraction-based (scatterometry) overlay measurements for alignment of a subsequent mask. When a wafer is processed, the wafer includes a device area corresponding to the functional circuitry of an integrated circuit and an overlay mark region that includes periodic structures or gratings that are used for diffraction-based scatterometry to enable alignment for formation of subsequent features. The overlay region includes a shield grating of elongated structures, a bottom grating of first elongated conductive structures, and a top grating of second elongated conductive structures above the bottom grid of first elongated conductive structures. Multiple first conductive structures may be positioned laterally between pairs of adjacent second conductive structures. This results in improved alignment for subsequently formed conductive structures such as conductive vias and metal lines. The result is improved wafer yields and better functioning integrated circuits.

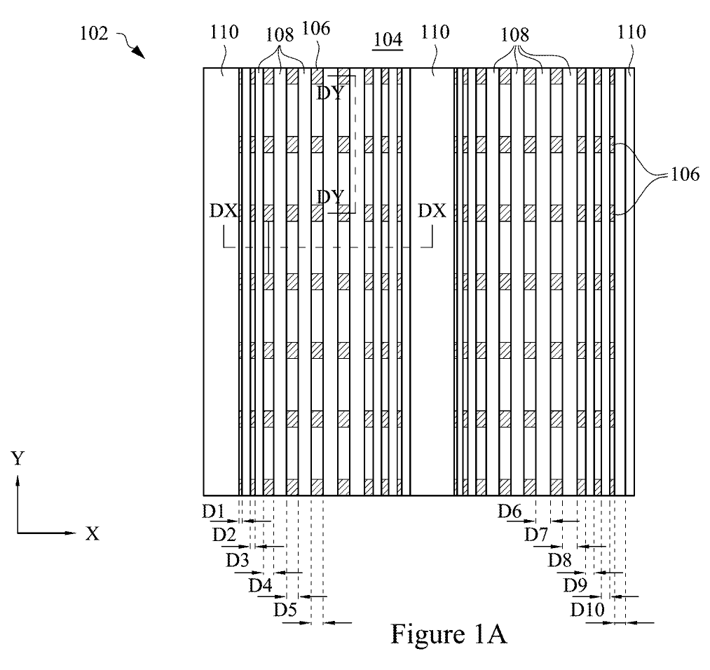

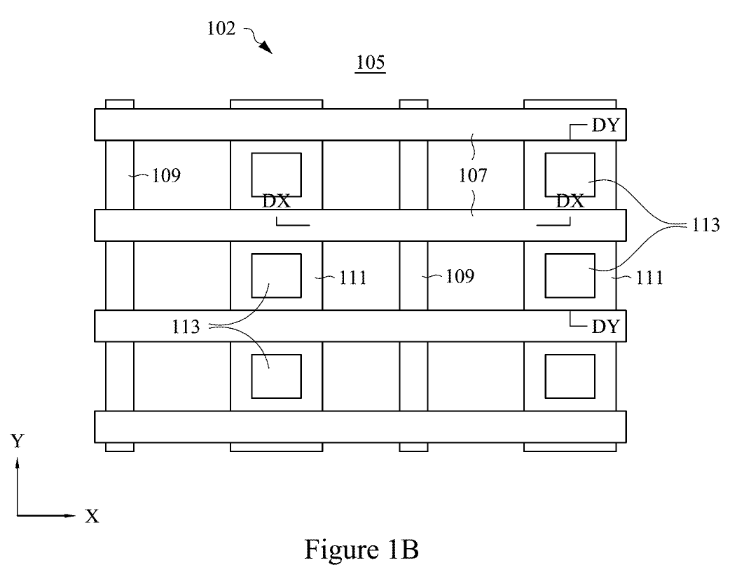

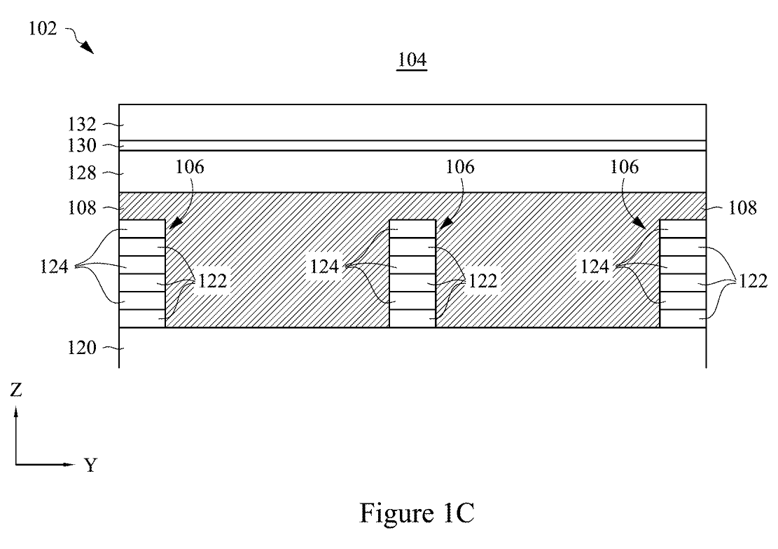

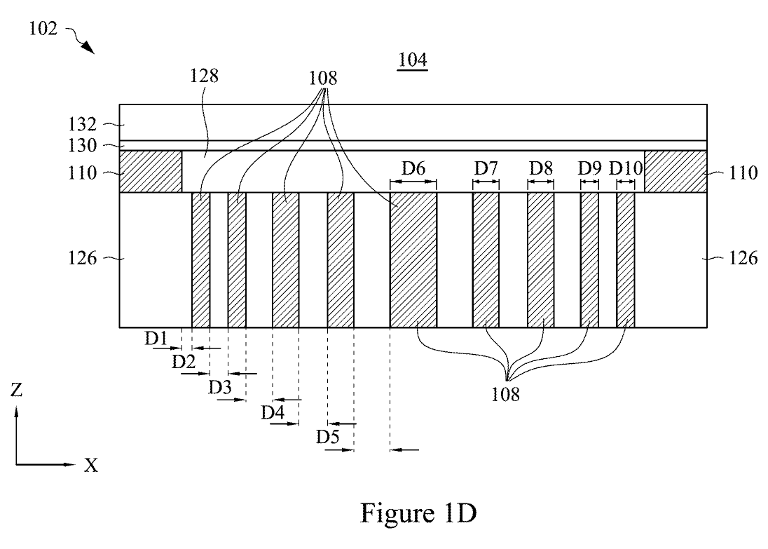

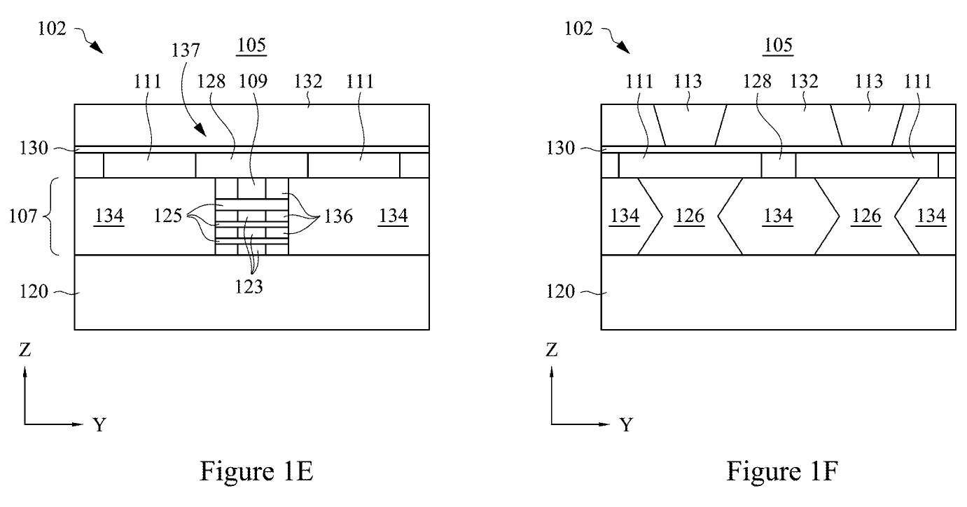

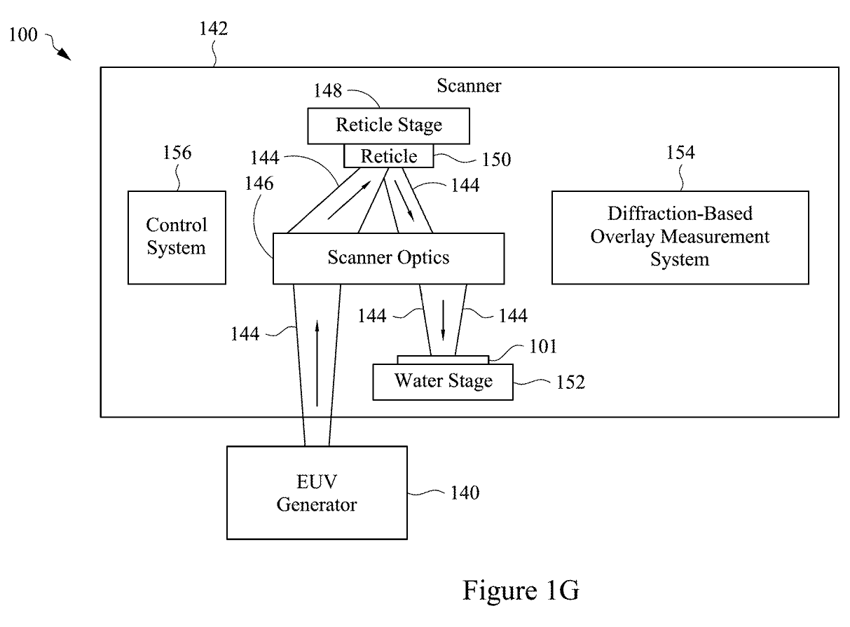

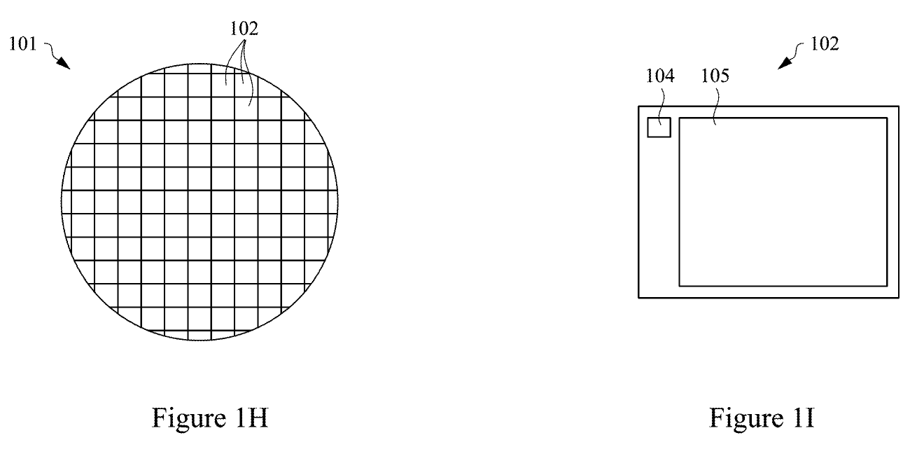

FIG. 1A is a top view of an integrated circuit 102 at an intermediate stage of processing, in accordance with some embodiments. More particularly, FIG. 1A is a top view of an overlay mark region 104 of the integrated circuit 102. FIG. 1B is a top view of a device region of the integrated circuit 102, in accordance with some embodiments. As will be set forth in more detail below, the components of the overlay mark region 104 are configured to collectively enable a diffraction-based overlay scan to be performed accurately in order to assist in aligning a subsequent mask used to form subsequent features.

Prior to describing the details of the overlay mark region 104 and the device region 105, it is beneficial to broadly describe the different functions of the device region 105 and the overlay mark region 104 The device region 105 includes the circuitry that makes up the integrated circuit. For example, when processing of the integrated circuit 102 is complete, the device region 105 may include a plurality of transistors including channel, source/drain, and gate regions. When processing of the device region 105 is complete, the device region 105 may include a plurality of metal layers stacked above the transistors and each formed on a respective interlevel dielectric layer. When processing of the device region 105 is complete, the device region 105 may include a plurality of conductive vias embedded in the interlevel dielectric layers and connecting source/drain contacts or gate contacts to metal zero (M0), the first metal layer to a second metal layer, and so forth.

When processing the integrated circuit 102, a large number of reticles (or masks) may be utilized to form patterns of features in the integrated circuit 102. Before using a reticle in a photolithography process with the integrated circuit 102, one or more alignment processes is performed. The alignment processes are performed so that the features formed in conjunction with the photolithography process will properly aligned with features that have already been formed in conjunction with previous reticles and photolithography processes.

The overlay mark region 104 assists in performing alignment processes throughout the processing of the integrated circuit 102. More particularly, the overlay mark region 104 assists in performing overlay diffraction-based (scatterometry) measurement processes to assist in alignment. The overlay mark region 104 includes multiple grating structures. The overlay diffraction-based process irradiates the overlay mark region 104 with selected wavelengths of light and measures the scattered light. The scattered light will have features based on the positions of the uppermost grating based on diffraction of the light from the grating. The features of the scattered light can help determine proper alignment for the next photolithography exposure.

The stage of processing shown in FIG. 1A corresponds to a stage of processing in which source/drain regions of transistors have been formed, source/drain contact structures have been formed in contact with the source/drain regions. An overlay diffraction-based measurement process utilizing the overlay mark region 104 may be utilized to align a mask utilized to form conductive vias in contact with the source/drain contacts. FIG. 1B illustrates the device region 105 at a subsequent stage of processing in which the conductive vias have been formed in conjunction with the overlay diffraction-based process utilizing the overlay mark region 104.

FIGS. 1A and 1B illustrate one example in which principles of the present disclosure are utilized to align and form conductive vias in contact with source/drain metals. However, principles of the present disclosure can be utilized to provide an overlay mark region for alignment in forming a first metal layer including metal tracks that are in contact with the tops of the conductive vias. Accordingly, the structure of the overlay mark region 104 at the stage of processing shown in FIG. 1A will be utilized to ensure that an effective overlay diffraction-based process can be performed to align the next reticle so that subsequently formed structures will be properly aligned and in contact with previously form structures.

With reference to FIG. 1A, the overlay mark region 104 includes a shielding grating including a plurality of elongated structures 106 extending the X-direction. In some embodiments, the elongated structures of the shield grating 106 correspond to a plurality of semiconductor fins, though other types of elongated structures can be utilized for the shield grating without departing from the scope of the present disclosure. For example, the elongated structures 106 of the shield grating can include dielectric fins, photo resist fins, conductive fins, metal lines or other types of elongated structures.

The elongated structures 106 of the shield grating each extend in the X direction and are spaced apart from each other in the Y direction. Though not apparent in the view of FIG. 1A, the elongated structures 106 of the shield grating may be positioned on a substrate. The elongated structures 106 of the shield grating have a pitch in the Y direction of between 10 nm and 50 nm, though other pitch values can be utilized without departing from the scope of the present application. The elongated structures 106 of the shield grating have a width in the Y direction of between 10 nm and 50 nm, though other pitch values can be utilized without departing from the scope of the present application. Details regarding the materials of the elongated structures 106 of the shield grating are provided further below. As will be described in more detail below, the elongated structures 106 may be formed in a same process and of a same material as semiconductor fins from which the channels and source/drain regions of transistors will be formed in the device region 105.

The overlay mark region 104 includes a bottom grating of elongated conductive structures 108 extending in the X direction and separated from each other in the Y direction. Though not shown in FIG. 1A, the bottom grating of the elongated conductive structures 108 is positioned on the substrate between adjacent elongated structures 106. The conductive structures 108 have varying pitches in the Y direction, as will be described in more detail below.

Prior to describing further details regarding the bottom grating of the elongated conductive structures 108, it is beneficial to describe the top grating of elongated conductive structures 110. The elongated conductive structures 110 extend in the Y direction and are separated from each other in the X direction. The overlay mark region 104 includes a grating of first conductive structures 110. The first metal structures are positioned directly over the semiconductor fins 106. Though not shown in FIG. 1A, the first conductive structures 110 are formed on a dielectric layer that overlies the semiconductor fins 106. The first conductive structures 110 extend in the X direction and are separated from each other in the Y direction. The first conductive structures 110 have a pitch of between 20 nm and 100 nm, though other pitch values can be utilized without departing from the scope of the present application. The first conductive structures 110 each have a width in the Y direction of between 10 nm and 50 nm, though other width values can be utilized without departing from the scope of the present application.

In one possible solution, there is a single elongated conductive structure 108 between each pair of elongated conductive structures 110. However, the overlay mark region 104 of FIG. 1A includes a bottom grating of conductive structures 108 in which a plurality of conductive structures are positioned laterally between each pair of conductive structures 110 of the top. This can provide several benefits. For example, the different pattern sizes of the bottom grating with respect to the top. Results in a material difference (n/k) and the interference range. This can result in increased accuracy and alignment processes based on diffraction-based overlay. As can be particularly useful because of different sensitivities of polarization sources to vertical and horizontal patterns.

In some embodiments, the conductive structures of the bottom grating are separated from each other and from the conductive structures 110 of the top grating by differing dimensions. In the example of FIG. 1A, the leftmost conductive structure 108 of the bottom grating between the left and middle conductive structures 110 of the top grating will be termed a first conductive structure 108. The first conductive structure 108 of the bottom grating to the leftmost conductive structure 110 of the top grating is separated from the conductive structure 110 by a dimension D1. The second conductive structure 108 is separated from the first conductive structure 108 by a dimension D2. The third conductive structure is separated from the second conductive structure 108 by a dimension D3. The fourth conductive structure 108 is separated from the third conductive structure 108 by a dimension D4. The fifth conductive structure is separated from the fourth conductive structure 108 by a dimension D5. The sixth 108 conductive structure may be separated from the fifth conductive structure 108 by the dimension D5. The seventh conductive structure may be separated from the sixth conductive structure 108 by the dimension D4. The eighth conductive structure 108 may be separated from the seventh conductive structure 108 by the dimension D3. The ninth conductive 108 structure may be separated from the eighth conductive structure 108 by the dimension D2. The second conductive structure 110 of the top. Maybe separated from the ninth conductive structure 108 by the dimension D1.

In some embodiments, the dimension D1 is less than the dimension D2. The dimension D2 is less than the dimension D3. The dimension the D3 is less than the dimension D4. The dimension D4 is less than the dimension D5. Alternatively, the dimensions D1 and D2 may be the same. The dimensions D3 and D4 may be the same. In the dimension D5 may be the same.

In some embodiments, the dimension D1 is between 0 nm and 30 nm. In some embodiments, the dimension D2 is between 24 nm and 76 nm. In some embodiments, the dimension D3 is between 24 nm and 76 nm. In some embodiments, the dimension D4 is between 24 nm and 76 nm. In some embodiments, the dimension D5 is between 24 nm and 76 nm. Other dimensions can be utilized without departing from the scope of the present disclosure. Other numbers of conductive structures 108 of the bottom grating may be positioned between adjacent pairs of conductive structures 110 of the top grating without departing from the scope of the present disclosure.

In some embodiments, the conductive structures 108 of the bottom grating between a pair of conductive structures 110 of the top grating may have differing widths. With reference to the conductive structures 108 of the bottom grating between the middle and right conductive structures 110 of the top grating, a middle conductive structure 108 may have a width dimension D6. A next conductive structure 108 to the right may have a width dimension D7. A next conductive structure 108 to the right may have a width dimension D8. A next conductive structure 108 to the right may have a width dimension D9. A next conductive structure 108 to the right (the nearest to the right conductive structure 110 of the top grating) may have a width dimension D10.

In some embodiments, the dimension D10 is less than the dimension D9. The dimension D9 is less than the dimension D8. The dimension the D8 is less than the dimension D7. The dimension D7 is less than the dimension D6. Alternatively, the dimensions D8, D9, and D10 may be the same. The dimensions D6 and D7 may be the same.

In some embodiments, the dimension D6 is between 24 nm and 80 nm. In some embodiments, the dimension D7 is between 24 nm and 80 nm. In some embodiments, the dimension D8 is between 24 nm and 80 nm. In some embodiments, the dimension D9 is between 24 nm and 80 nm. In some embodiments, the dimension D10 is between 24 nm and 80 nm. Other dimensions can be utilized without departing from the scope of the present disclosure.

The structures 108 can include polysilicon, or another material. As will be described in more detail below, in some embodiments the structures 108 are formed in the same material and the same process as dummy gate structures that will be in the device region 105 and that correspond to locations of gate metals that will subsequently be formed. In some embodiments, the first conductive structures 110 are formed of a same material and in a same deposition process as source/drain contact metals that are formed in the device region 105. The first conductive structures 110 can include tungsten, titanium, tantalum, aluminum, copper, gold, or other suitable conductive materials.

With reference to FIG. 1B, the device region 105 includes semiconductor fins 107. The semiconductor fins 107 correspond to OD regions in which channel regions and source/drain regions of transistors will be formed. The semiconductor fins 107 extends in the X direction and are separated from each other in the Y direction. The semiconductor fins 107 are initially formed in a same process that forms the semiconductor fins 106 of the overlay mark region, though subsequent processing changes the composition of the semiconductor fins 107, as will be described in more detail below.

The device region 105 includes conductive structures 109. The conductive structures 109 correspond to the location at which gate metals will be formed in subsequent processes. Though not shown in FIG. 1B, the conductive structures 109 are formed on a same substrate as the semiconductor fins 107. However, the conductive structures 109 are formed after the semiconductor fins 107 and overly the semiconductor fins 107 when they cross the semiconductor fins 107. The conductive structures 107 may be described as dummy gate structures. The conductive structures 109 are initially formed in a same process that forms the conductive structure 108 of the bottom grating overlay mark region 104.

The device region 105 includes source/drain contacts 111. The source/drain contacts 111 overlie and are in contact with the source/drain regions (not shown in FIG. 1B) formed in the semiconductor fins 107. The source/drain contacts 111 are the same material and formed in a same deposition process as the first conductive structures 110 of the overlay mark region 104. The source/drain contacts 111 correspond to metal connection structures.

As described previously, FIG. 1B illustrates the device region 105 at a subsequent stage of processing to FIG. 1A. In particular, a diffraction-based overlay processes been performed to align a mask for formation of the conductive vias 113 in contact with the source/drain contacts 111 using the overlay mark region 104 of FIG. 1A. Accordingly FIG. 1B illustrates the device region 104 after the alignment process has been performed and the conductive vias 113 have been formed. The conductive vias 113 are in contact with the top of the source/drain contacts 111 and provide electrical connection to the source/drain contacts 111. The conductive vias 113 correspond to metal connection structures. Other metal connection structures that can be formed in accordance with principles of the present disclosure are metal lines or other types of connection structures for providing electrical connection throughout the device region 105.

FIG. 1C is a cross-sectional view of the overlay mark region 104 taken along cut lines OY, in accordance with some embodiments. The integrated circuit includes a substrate 120. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The elongated structures 106 are positioned on the substrate 120. In some embodiments, the elongated structures 106 are semiconductor fins and include a plurality of semiconductor layers 124 and sacrificial semiconductor layers 122 alternating with each other. In some embodiments, the semiconductor layers 124 may be formed of a first semiconductor material suitable for semiconductor nanostructure transistors, such as silicon, silicon germanium, silicon carbide, or the like, and the sacrificial semiconductor layers 122 may be formed of a second semiconductor material that is selectively etchable with respect to the material of the semiconductor layers 124, such as silicon germanium, silicon, or the like. Each of the layers of the semiconductor fin 106 may be epitaxially grown using a process such as chemical vapor deposition (CVD), atomic layer deposition (ALD), vapor phase epitaxy (VPE), molecular beam epitaxy (MBE), or the like.

The conductive structures 108 are positioned on the substrate 120. The conductive structures 108 are positioned between the semiconductor fins 106. Though not apparent in FIG. 1C, an interlevel dielectric layer 126 is positioned on the substrate 120 the semiconductor fins 120 between the elongated structures 106 and the conductive structures 108, and has a top surface substantially coplanar with the top surface of the semiconductor structures 108 (see FIG. 1D). The interlevel dielectric layer 126 can include silicon oxide silicon nitride, SiCO, SiCN, SiCON, or other suitable dielectric materials.

The integrated circuit 102 includes an interlevel dielectric layer 128 on the dielectric layer 126. The interlevel dielectric layer 128 can include silicon oxide silicon nitride, SiCO, SiCN, SiCON, or other suitable dielectric materials. The interlevel dielectric layer 128 may have a top surface that is substantially coplanar with a top surface of the conductive structures 110.

The integrated circuit 102 includes a dielectric layer 130 on the interlevel dielectric layer 128 and on the conductive structures 110. The dielectric layer 128 can include silicon nitride or other suitable dielectric materials.

The integrated circuit 102 includes an interlevel dielectric layer 132 on the dielectric layer 130. The interlevel dielectric layer 132 can include silicon oxide silicon nitride, SiCO, SiCN, SiCON, or other suitable dielectric materials.

FIG. 1D is a cross-sectional view of the overlay mark region 104 taken on cut lines X of FIG. 1A. The first conductive structures 110 are positioned on the top surface of the dielectric layer 126. The first conductive structures 110 can include Al, W, Ti, TiN, Ta, Co, or other suitable conductive materials. The first conductive structures 110 can have a height in the Z direction between 5 nm and 100 nm, though other height values can be utilized without departing from the scope of the present application. Other materials and thicknesses can be utilized for the first conductive structures 110 without departing from the scope of the present disclosure.

The integrated circuit 102 includes an interlevel dielectric layer 128 on the dielectric layer 126. The interlevel dielectric layer 128 can include silicon oxide silicon nitride, SiCO, SiCN, SiCON, or other suitable dielectric materials. The interlevel dielectric layer 128 may have a top surface that is substantially coplanar with a top surface of the conductive structures 110.

The integrated circuit 102 includes a dielectric layer 130 on the interlevel dielectric layer 128 and on the conductive structures 110. The dielectric layer 128 can include silicon nitride or other suitable dielectric materials.

The integrated circuit 102 includes an interlevel dielectric layer 132 on the dielectric layer 130. The interlevel dielectric layer 132 can include silicon oxide silicon nitride, SiCO, SiCN, SiCON, or other suitable dielectric materials.

FIGS. 1E and 1F are cross-sectional views of the device region 105 of the integrated circuit 102, in accordance with some embodiments. The view of FIG. 1E is taken along cut lines DX in FIG. 1B. The view of FIG. 1F is taken along cut lines DY in FIG. 1B.

With reference to FIG. 1E, the semiconductor stack 107 has been processed to produce stacked channels 125 and source/drain regions 134 of a gate all around nanostructure transistor. The sacrificial semiconductor nanostructures 123 are positioned between the stacked channels 136. The channels 125 are the same material as the semiconductor layers 124. The sacrificial semiconductor nanostructures 123 are a same material as the semiconductor layers 122.

The channels 125 may correspond to semiconductor nanostructures and may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

The channels 125 may also be termed semiconductor nanosheets, though other types of semiconductor nanostructures can be utilized without departing from the scope of the present disclosure. The channels 125 can include a monocrystalline semiconductor material such as silicon, silicon germanium, or other semiconductor materials. The channels 125 may be an intrinsic semiconductor material or may be a doped semiconductor material. The semiconductor nanostructures may include nanosheets, nanowires, or other types of nanostructures. The channels 125 may have a thickness in the Z direction between 2 nm and 5 nm. The channels 125 may have a width in the X direction between 5 nm and 15 nm. Other materials and dimensions can be utilized for the channels 125 without departing from the scope of the present disclosure.

Inner spacers 136 have also been formed in recesses formed in the sacrificial semiconductor nanostructures 123. The inner spacers 136 can include silicon oxide, silicon nitride, SiCN, SiCON, SiCO, or other suitable dielectric materials. The inner spacers 136 electrically isolate the source/drain regions 134 from gate metals (not shown).

Although FIG. 1B illustrates the conductive structures 109 and the sacrificial semiconductor nanostructures 123 as being present, in practice, at the stage of processing shown in FIG. 1B the conductive structures 109 and the sacrificial semiconductor nanostructures 123 may already be replaced with one or more gate metals that wrap around the channels 125 and that fill the space left by the sacrificial semiconductor nanostructures and the conductive structures 109.

The source/drain regions 134 can be formed by etching the semiconductor fin 107 outside of the channels 125 and then performing an epitaxial growth to regrow the source/drain regions 134. The source/drain regions 134 can be doped with P type or N type dopants in situ during the epitaxial growth process.

The transistor 137 may include a gate dielectric (not shown) positioned between the channels 125 and the gate metal. The channels 125 extend in the X direction between the source/drain region 134.

Source/drain contacts 111 are positioned on the source/drain regions 134. The source/drain contacts 111 correspond to metal structures that are electrically and physically coupled to the source/drain regions 134. The source/drain contacts 111 are formed of a same material and in a same deposition process as the first conductive structures 110. Though not shown in FIG. 1E, a layer of silicide may be positioned directly between the source/drain regions 134 and the source/drain contacts 111. FIG. 1E also illustrates the dielectric layers 128, 130, and 132 which are as described in relation to FIG. 1C.

The transistor 137 may generally operate in the following manner. A gate voltage may be applied to the gate metal (not shown) to render the channels 125 conducting or nonconducting. In the example of an N-channel transistor, a gate voltage of ground may turn off the transistor 137, while a gate voltage of VDD may turn on the transistor 137. In the example of a P-channel transistor, a gate voltage of ground may turn on the transistor 137 while a gate voltage of VDD may turn off the transistor 137. If the transistor 137 is turned on and there is a voltage difference between the source/drain regions 134, then a current may flow between the source/drain regions 134 through each of the channels 106. Voltages may be applied to the source/drain regions 134 via the portions of the source/drain contacts 111. The conductive vias 113 are not shown in the view of FIG. 1E.

FIG. 1F illustrates the dielectric layer 126 between the source/drain regions 134 in the Y direction. FIG. 1F also illustrates source/drain contacts 111 positioned on the interlevel dielectric layer 126. FIG. 1 the illustrates the conductive vias 113 extending through the dielectric layers 132 and 130 and connecting with contacting the source/drain contacts 111.

As set forth previously, the conductive vias 113 have been formed in conjunction with a diffraction-based overlay measurement process utilizing the bottom grating of conductive structures 108 and the top grating of conductive structures 110 in the overlay mark region 104. Is now ready for a diffraction-based overlay measurement process utilizing the second metal structures 112 of the overlay mark region 104 as a diffraction grating. The presence of the multiple conductive structures 108 of the bottom grating between pairs of conductive structures 110 of the top grating helps ensure that the diffraction-based overlay measurement will effectively assist in the alignment process to form subsequent metal lines.

FIG. 1G is a block diagram of an EUV photolithography system 100, in accordance with some embodiments. Description of the EUV photolithography system 100 assist in understanding of the overall photolithography process of which diffraction-based overlay measurement plays a part. Notably, the photolithography system 100 includes an EUV generator 140, a scanner 142, and a diffraction-based overlay measurement system 154 within the scanner 142. As used herein, the terms “EUV light” and “EUV radiation” can be used interchangeably. While description of the FIG. 1F may primarily focus on EUV photolithography, principles of the present disclosure extend to photolithography processes other than EUV photolithography processes.

The EUV generator 140 generates EUV light. The EUV generator may include a droplet generator, an EUV light generation chamber, a droplet receiver, a scanner 142, and a laser. The droplet generator outputs droplets into the EUV light generation chamber. The laser irradiates the droplets with pulses of laser light within the EUV light generation chamber. The irradiated droplets emit EUV light 144. The EUV light 144 is collected by a collector and reflected toward the scanner 142. The scanner 142 conditions the EUV light 144, reflects the EUV light 144 off of reticle 150 including a mask pattern, and focuses the EUV light 144 onto the wafer 101. The EUV light 144 patterns a layer on the wafer 101 in accordance with a pattern of the reticle 150. Each of these processes is described in more detail below. The wafer 101 includes a plurality of integrated circuits 102.

The scanner 142 includes scanner optics 146. The scanner optics 146 include a series of optical conditioning devices to direct the EUV light 144 to the reticle. The scanner optics 146 may include refractive optics such as a lens or a lens system having multiple lenses (zone plates). The scanner optics 146 may include reflective optics, such as a single mirror or a mirror system having multiple mirrors. The scanner optics 146 direct the ultraviolet light from the EUV light generation chamber to a reticle 150.

FIG. 1G illustrates a reticle 150 within the scanner 142. The reticle 150 is mounted on a reticle stage 148. The reticle stage can translate in the X, Y, and Z directions in order to properly aligned with the wafer 101.

During an EUV exposure process, EUV light 144 reflects off of the reticle 150 back toward further optical features of the scanner optics 146. In some embodiments, the scanner optics 146 include a projection optics box. The projection optics box may have refractive optics, reflective optics, or combination of refractive and reflective optics. The projection optics box directs the EUV light 144 onto the wafer 101, for example, a semiconductor wafer.

The EUV light 144 includes a pattern from the reticle 150. In particular, the reticle 150 includes the pattern to be defined in the wafer 101. After the EUV light 144 reflects off of the reticle 150, the EUV light 144 contains the pattern of the reticle 150. A layer of photoresist typically covers the wafer 101 during extreme ultraviolet photolithography irradiation. The photoresist assists in patterning a surface of the semiconductor wafer 101 in accordance with the pattern of the reticle.

A wafer stage 152 may hold the wafer 101 during photolithography processes. The wafer stage can translate in the X, Y, and Z directions. This can assist in aligning the wafer 101 and the reticle 150.

The diffraction-based overlay measurement system 154 performs diffraction-based overlay measurements to assist in aligning the wafer 101 and the reticle 150. The wafer 101 may include a large number of integrated circuits 102. Each exposure may pattern a single integrated circuit of the wafer 101. Accordingly, the diffraction-based overlay measurement system 154 may perform diffraction-based overlay measurements for each integrated circuit of the wafer 101. The diffraction-based overlay measurement system 154 irradiates the wafer 101 with selected wavelengths of light, for example, between 400 nm and 850 nm. More particularly, the diffraction-based overlay measurement system 154 irradiates the overlay mark region 104 of the integrated circuit 102 for which alignment is being performed. The grating of second metal structures 112 acts as a diffraction grating and the facts the light from the diffraction-based overlay measurement system 154. The diffraction-based overlay measurement system 154 senses the diffracted light and calculates alignment or misalignment based on the diffracted light.

The scanner 142 may include a control system 156 that controls the components of the system 100. The control system 156 may be coupled to the diffraction-based overlay measurement system 154 and may adjust the positions of the wafer 101 and the reticle 150 based, at least in part, on the diffraction-based overlay measurement system 154.

FIG. 1H is a top view of a wafer 101, in accordance with some embodiments. The wafer 101 can correspond to a semiconductor wafer including a plurality of identical integrated circuits 102. During patterning, each integrated circuit 102 may be individually exposed to EUV light via the reticle 150.

FIG. 1I illustrates a simplified top view of an integrated circuit 102 of the wafer 101, in accordance with some embodiments. The integrated circuit 102 includes an overlay mark region 104 and a device region 105. The overlay mark region 104 includes the structures shown and described in relation to FIGS. 1A, 1C and 1D. Although a single overlay mark region 104 is illustrated in FIG. 1I, in practice and integrated circuit 102 may include multiple overlay mark regions 104. The device region 105 may include features and structures shown and described in relation to FIGS. 1B-1E, and 1F, as well as other types of features and structures not shown.

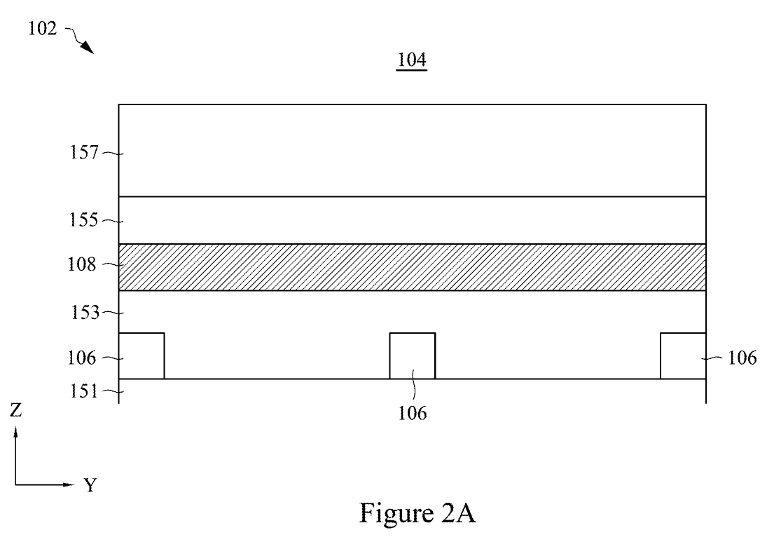

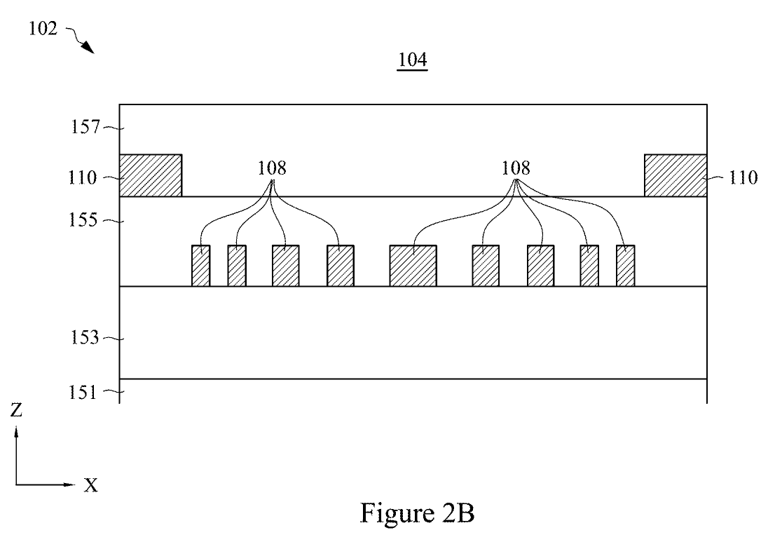

FIGS. 2A and 2B are cross-sectional views of the overlay mark region 104 of FIG. 1A, in accordance with some embodiments. In FIGS. 2A and 2B, the elongated structures 106 of the shield grating are formed on a top surface of an interlevel dielectric layer 150 and are covered by an interlevel dielectric layer 152. The conductive structures 108 of the bottom grating are formed on the top surface of the interlevel dielectric layer 152 and are covered by an interlevel dielectric layer 154. The conductive structures 110 of the top grating are formed on a top surface of the interlevel dielectric layer 154 and recovered by an interlevel dielectric layer 156. The dimensions D1-D10 of FIGS. 1A, 1C, and 1D can be utilized. The lateral spacings of FIGS. 2A and 2B can be the same as in FIGS. 1A, 1C, and 1D. The materials of the elongated structures 106, the conductive structures 108, and the conductive structures 110 can be as described previously can be different materials than described previously. In some embodiments, the bottom grating of conductive structures 108 and the top grating of conductive structures 110 can be utilized to align the mask for patterning the metal lines or for forming conductive vias. The materials of the interlevel dielectric layers 150, 152, 154, and 156 can be as described for the layers 120, 128, 130, and 132 in relation to FIGS. 1A, 1C, and 1D.

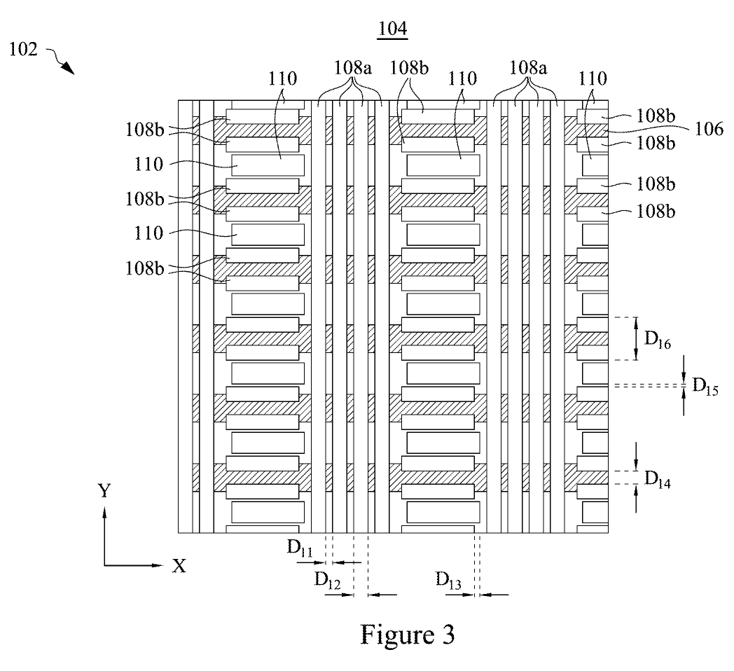

FIG. 3 illustrates an overlay mark region 104 of an integrated circuit 102, in accordance with some embodiments. The overlay mark region 104 includes a shield grating of elongated structures 106. The elongated structures 106 can be substantially as described in relation to FIGS. 1A, 1C, and 1D or 2A and 2B. The overlay mark region 104 can utilize processes, components, structures, and the relative vertical positions described in relation to FIGS. 1A-2B.

The overlay mark region 104 includes a bottom grating of elongated conductive structures 108. The bottom grating of conductive structures 108 includes elongated constructive structures 108a and elongated conductive structures 108b. The conductive structures 108 can have a same material as described in relation to FIG. 1A, 1C, and 1D or FIGS. 2A and 2B. The conductive structures 108 can also be formed on a same substrate 120 as the elongated structures 106 as described in relation to FIGS. 1C and 1D or can be formed on different interlevel dielectric layers as described in relation to FIGS. 2A and 2B.

The overlay mark region 104 includes a top grating of elongated conductive structures 110. The conductive structures 110 can have a same material as described in relation to FIGS. 1A, 1C, and 1D. The conductive structures 110 can also be formed on an interlevel dielectric layer as described in relation to FIGS. 1C and 1D or 2A and 2B.

The bottom grating of conductive structures 108 includes multiple patterns. A first pattern includes groups of conductive structures 208. A second pattern includes groups of conductive structures 308. The conductive structures 208 extend in the Y direction and are separated from each other in the X direction. Each group of conductive structures 208 includes four conductive structures 208. Each conductive structure 208 extends across a plurality of elongated structures 106 of the shield grating. In FIG. 3, the conductive structures 208 of a group each have a same dimension D12 and are separated from each other by a same separation distance D11. The dimension D11 can be between 24 nm and 76 nm. The dimension D12 can be between 24 nm and 80 nm. However, in some embodiments the conductive structures 208 of the group can have different widths and can be separated from each other by different separation distances. Furthermore, the conductive structures 208 can include a different number than for conductive structures 208 in each group.

The conductive structures 308 extend in the X direction and are separated from each other in the Y direction. Each group of conductive structures 308 includes two conductive structures 308 between adjacent pairs of conductive structures 110 of the top grating. Each conductive structure 308 is positioned overlapping a same elongated structure 106. Each conductive structure 110 of the top grating extends past the adjacent conductive structure 308 of the bottom grating by distance D13. Each conductive structure 308 of a pair separated from each other in the Y direction by a dimension D14. Each conductive structure 308 is separated from an adjacent conductive structure 110 of the top grating by a dimension D15 in the Y direction. Each pair of conductive structures 110 are separated from each other by a dimension D16. D13 can be between 105 nm and 145 nm. D14 can be between 42 nm and 72 nm. D15 can be between 1 nm and 31 nm. D16 can be between 180 nm and 240 nm. Other distances can be utilized without departing from the scope of the present disclosure.

Adjacent groups of conductive structures 308 of the bottom grating and conductive structures 110 of the top grating can be good thing columns. Each column of conductive structures 308 of the bottom hundred and conductive structures 110 of the top grating can be positioned between adjacent groups of conductive structures 208 of the bottom grating.

The overlay mask region 104 of FIG. 3 can be utilized to form the device region 105 of FIGS. 1B, 1E and 1F or metal interconnects or conductive vias as described in relation to FIGS. 2A and 2B.

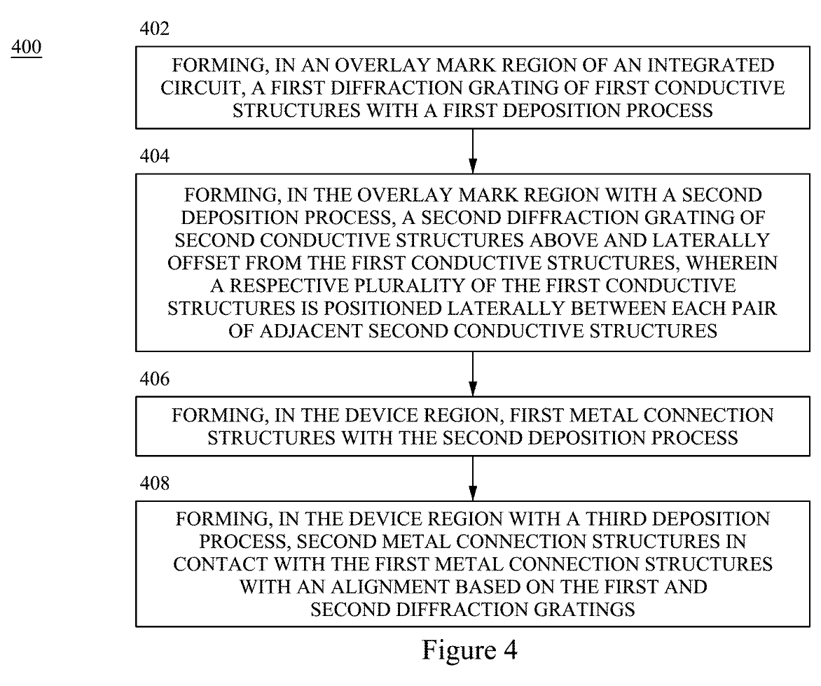

FIG. 4 is a flow diagram of a method 400, in accordance with some embodiments. The method 400 can utilize components, processes, and systems described in relation to FIGS. 1A-3. At 402, the method 400 includes forming, in an overlay mark region of an integrated circuit, a first diffraction grating of first conductive structures with a first deposition process. One example of an overlay mark region is the overlay mark region 104 of FIG. 1A. One example of a first diffraction grating of first conductive structures is the diffraction grating of first conductive structures 108 of FIG. 1A. At 404, the method 400 includes forming, in the overlay mark region with a second deposition process, a second diffraction grating of second conductive structures above and laterally offset from the first conductive structures, wherein a respective plurality of the first conductive structures is positioned laterally between each pair of adjacent second conductive structures. One example of a second grating of second conductive structures is the grating of second conductive structures 110 of FIG. 1A. At 406, the method 400 includes forming, in the device region, first metal connection structures with the second deposition process. One example of a device region is the device region 105 of FIG. 1E. One example of first metal connection structures are the source/drain contacts 111 of FIG. 1E. At 408, the method 400 includes forming, in the device region with a third deposition process, second metal connection structures in contact with the first metal connection structures with an alignment based on the first and second diffraction gratings. One example of second metal connection structures are the conductive vias 113 of FIG. 1F.

Embodiments of the present disclosure provide a method and structure for improved alignment of features in wafer processing. Embodiments of the present disclosure provide an enhanced overlay mark region that enables improved diffraction-based (scatterometry) overlay measurements for alignment of a subsequent mask. When a wafer is processed, the wafer includes a device area corresponding to the functional circuitry of an integrated circuit and an overlay mark region that includes periodic structures or gratings that are used for diffraction-based scatterometry to enable alignment for formation of subsequent features. The overlay region includes semiconductor fins spaced apart from each other and extending in a first direction, dummy gate structures positioned between the semiconductor fins and extending in a same direction, a grating of first metal structures of source/drain contact material aligned over the semiconductor fins, and a grating of second metal structures of a conductive via material aligned over the dummy gate structures at a level higher than the first metal structures.

The use of the grating of first metal structures in the overlay mark region assist in ensuring that the second metal structures have a selected height after a subsequent chemical mechanical planarization (CMP) process. The selected height is a height sufficient to ensure that a subsequent diffraction-based overlay measurement process provides a strong signal that can be used for proper alignment of a subsequent mask used to form metal lines that contact the source/drain vias. The proper alignment results in metal lines that are reliably formed in contact with conductive vias. If the grating of first metal structures is not present at the overlay mark region, then after the CMP process the second metal structures may not have a sufficient height to enable a strong diffraction-based overlay measurement signal. Accordingly, the use of the grating of first metal structures in the overlay mark region results in better functioning integrated circuits and higher wafer yields.

In some embodiments, an integrated circuit includes an overlay mark region including a shield grating of elongated structures, a first diffraction grating of first conductive structures including a plurality of first groups of the first conductive structures, and a second diffraction grating of second conductive structures above the first diffraction grating of first conductive structures and the shield grating, wherein a respective first group of the first conductive structures is positioned laterally between each pair of adjacent second conductive structures.

In some embodiments, an integrated circuit includes a device region including a source/drain region of the transistor and a first metal connection structure of a first material electrically coupled to the source/drain region. The integrated circuit includes an overlay mark region including a first diffraction grating of first conductive structures and a second diffraction grating of second conductive structures of the first material above and offset from the first conductive structures. A plurality of the first conductive structures is positioned laterally between each pair of adjacent second conductive structures.

In some embodiments, a method includes forming, in an overlay mark region of an integrated circuit, a first diffraction grating of first conductive structures with a first deposition process. The method includes forming, in the overlay mark region with a second deposition process, a second diffraction grating of second conductive structures above and laterally offset from the first conductive structures. A respective plurality of the first conductive structures is positioned laterally between each pair of adjacent second conductive structures. The method includes forming, in the device region, first metal connection structures with the second deposition process and forming, in the device region with a third deposition process, second metal connection structures in contact with the first metal connection structures with an alignment based on the first and second diffraction gratings.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
an overlay mark region including:
a shield grating of elongated structures;
a first diffraction grating of first conductive structures including a plurality of first groups of the first conductive structures; and
a second diffraction grating of second conductive structures above the first diffraction grating of first conductive structures and the shield grating, wherein a respective first group of the first conductive structures is positioned laterally between each pair of adjacent second conductive structures.

2. The integrated circuit of claim 1, wherein the elongate structures extend in a first direction, wherein the first conductive structures and the second conductive structures extend in a second direction transverse to the first direction.

3. The integrated circuit of claim 2, wherein each first group includes first conductive structures of differing widths.

4. The integrated circuit of claim 2, wherein each first group includes multiple different separation distances between adjacent pairs of the first conductive structures of the first group.

5. The integrated circuit of claim 1, wherein the elongated structures, the first conductive structures of each first group, and the second conductive structures each extend in a first direction.

6. The integrated circuit of claim 5, wherein the first diffraction grating includes a plurality of second groups of the first conductive structures each extending in a second direction transverse to the first direction.

7. The integrated circuit of claim 6, wherein the first conductive structure of the second groups each extend over multiple elongated structures.

8. The integrated circuit of claim 7, wherein each second group is positioned between two adjacent columns of first groups.

9. The integrated circuit of claim 5, wherein the second conductive structures and the first conductive structures of the first groups each have a same length.

10. The integrated circuit of claim 1, comprising a substrate, wherein the first conductive structures and the elongated structures are positioned on a top surface of the substrate.

11. The integrated circuit of claim 1, comprising:
a first interlevel dielectric layer on the elongated structures, wherein the first conductive structures are on a top surface of the first interlevel dielectric layer; and
a second interlevel dielectric layer on the first conductive structures, wherein the second conductive structures are on a top surface of the second interlevel dielectric layer.

12. An integrated circuit, comprising:
a device region including:
a source/drain region of a transistor; and
a first metal connection structure of a first material electrically coupled to the source/drain region;
an overlay mark region including:
a first diffraction grating of first conductive structures; and
a second diffraction grating of second conductive structures of the first material above and offset from the first conductive structures, wherein a plurality of the first conductive structures is positioned laterally between each pair of adjacent second conductive structures.

13. The integrated circuit of claim 12, wherein the device region includes a second metal connection structure of a second material in contact with the first metal connection structure.

14. The integrated circuit of claim 13, wherein the first metal connection structure is source/drain contact.

15. The integrated circuit of claim 14, wherein the overlay mark region includes a shield grating of elongated structures below the second diffraction grating.

16. The integrated circuit of claim 15, wherein the elongated structures are semiconductor fins.

17. The integrated circuit of claim 16, wherein the first conductive structures are polysilicon.

18. An integrated circuit, comprising:
an overlay mark region including:
a first diffraction grating of first conductive structures; and
a second diffraction grating of second conductive structures above and laterally offset from the first conductive structures, wherein a respective plurality of the first conductive structures is positioned laterally between each pair of adjacent second conductive structures;
a device region including:
first metal connection structures of a same material as the second conductive structures; and
second metal connection structures in contact with the first metal connection structures with an alignment based on the first and second diffraction gratings.

19. The integrated circuit of claim 18, wherein the first conductive structures are polysilicon.

20. The integrated circuit of claim 18, a shield grating of elongated structures below the second diffraction grating.
